(19) United States
(12) Patent Application Publication
(10) Pub. No.: US 2007/0029503 A1
(43) Pub. Date: Feb. 8, 2007

(54) GRID STRUCTURE FOR HOLDING SPECIMEN OF ELECTRON MICROSCOPY

(75) Inventor: Jae-Ryong JUNG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do (KR)

(21) Appl. No.: 11/461,716

(22) Filed: Aug. 1, 2006

(30) Foreign Application Priority Data
Aug. 2, 2005 (KR) 2005-0070758

(51) Int. Cl. H01J 37/20

(52) U.S. Cl. 250/440.11

(57) ABSTRACT

In an embodiment, a grid structure for holding a specimen of an electron microscopy is made up of materials which have etch resistance in ion etch processes such as FIB ion etch process or ion beam milling process. In the embodiment, the grid structure includes a first specimen holder for holding the specimen, a second specimen holder for holding the first specimen holder, and an adhesive for fixing the first holder and the second holder together. The first holder, here, is made up of at least one type of materials which are selected from silicon, titanium, carbon, vanadium, yttrium, or molybdenum.

### CROSS-REFERENCE TO RELATED APPLICATION

This application claims benefit of priority under 35 U.S.C. § 119 from Korean Patent Application No. 2005-70758 filed on Aug. 2, 2005, the disclosure of which is incorporated herein by reference in its entirety.

### BACKGROUND

1. Field of the Invention

The present invention relates to a part of electron microscopy. More particularly, the present invention relates to a grid structure for holding a specimen for electron microscopy.

2. Discussion of the Related Art

Electron microscopy uses a beam of electrons instead of light to magnify objects and can be classified as transmission, reflection, and scanning types depending on its principle of operation. Compared with an optical microscopy, electron microscopy offers an improvement in resolution and magnification, because an electron wavelength is much shorter than that of ordinary light.

Transmission Electron Microscopy (TEM) can magnify a specimen by about 1000˜1,000,000 times, and it can provide information on the specimen's structure based on refraction patterns. If used together with Energy Dispersive Spectroscopy (EDS), the TEM can also provide information on chemical properties of the specimen.

However, electron beams interact more strongly with materials than does light, so a specimen should be prepared to be very thin for an effective use of the electron microscopy. For instance, a thickness of a specimen less than 800 Å is generally required for valid measurements for recent semiconductor devices of high integration. The specimen having this thickness generally cannot be easily prepared by human hands, so an etch device is employed for etching a selected area of the specimen. The etch device may be a Focused Ion Beam (FIB), for example.

Preparing the specimen with the FIB includes, as shown in FIG. 1, making a preliminary specimen of a proper size that contains a target area for measurement (S10), and then attaching the preliminary specimen to a part of the electron microscopy apparatus called a grid (S20). Then the preliminary specimen, which is attached to the grid, is etched by means of the FIB (S30). Since high energy ions are used for the etch process, a damaged layer can be formed in the etched surface of the preliminary specimen. Accordingly, after the FIB etch process (S30) is carried out, an ion beam milling process is performed to remove the damaged layer from the etched surface of the preliminary specimen, and finally a specimen of a desired thickness is prepared (S40). The energy of ions during the ion beam milling process is lower than that at the FIB etch process.

The grid is typically made up of metal such as copper, nickel, etc. The FIB etch process and the ion beam milling process are a physical etch process utilizing kinetic energies of ions, so it is impossible to confine the etch process to just the specimen that is attached to the grid. Accordingly, because of this spill-over of ion energy to the grid, the grid is etched as well as the preliminary specimen. As a result, a metal layer, which originates from the grid, may be deposited on the surface of the specimen. This is called re-deposition. The re-deposition deteriorates the quality of an image of the electron microscopy, thereby causing great difficulty in properly analyzing the image. For instance, as shown in FIG. 2, the specimen's surface may be contaminated by the re-deposition causing the image quality of the electron microscopy to deteriorate. The fact that an EDS analysis detects metal materials confirms that these stains are indeed caused by the re-deposition.

Accordingly, the need exists for ways to prevent this sort of degradation in TEM image quality.

### SUMMARY

Embodiments provide a grid structure made up of material resistant to the ion etching process, in order to reduce the re-deposition. The grid structure may include a first specimen holder for holding a specimen, a second specimen holder for holding the first specimen holder, and an adhesive interposed between the first specimen holder and the second specimen holder to attach the first specimen holder to the second specimen holder. The first specimen holder is made up of at least one type of material selected from silicon, titanium, carbon, vanadium, yttrium, or molybdenum.

In other embodiments, a surface of the first specimen holder may be coated with at least one type of material selected from silicon, titanium, carbon, vanadium, yttrium, or molybdenum. The second specimen holder can also be made up of at least one type of material selected from silicon, titanium, carbon, vanadium, yttrium, or molybdenum. Otherwise, a surface of the second specimen holder may be coated with at least one type of material selected from silicon, titanium, carbon, vanadium, yttrium, or molybdenum.

In yet other embodiments, the grid structure includes a specimen holder for holding a specimen, and an adhesive interposed between the specimen and the specimen holder to attach the specimen to the specimen holder, or otherwise an interface to affix the specimen to the specimen holder. The specimen holder is made up of at least one type of material selected from silicon, titanium, carbon, vanadium, yttrium, or molybdenum.

In addition, a surface of the specimen holder can be coated with at least one type of material selected from silicon, titanium, carbon, vanadium, yttrium, or molybdenum.

### BRIEF DESCRIPTION OF THE DRAWINGS

The above and other advantages of the present invention will become readily apparent by reference to the following detailed description when considered in conjunction with accompanying drawings wherein:

FIG. 1 is a flow chart illustrating typical work processes of preparing a specimen for TEM (Transmission Electron Microscopy) analysis;

FIG. 2 is a TEM image that shows a re-deposition problem caused by a metal grid in a prior art;

FIG. 3 is a perspective view illustrating a grid structure according to one embodiment;

FIG. 4 is a graph illustrating sputtering yields measured from various materials;

FIG. 5 is an image taken by a TEM system with the grid structure of an embodiment;

FIG. 6A and FIG. 6B are perspective views illustrating cross-sections of the grid structures, according to a first exemplary embodiment;

FIG. 7A and FIG. 7B are perspective views illustrating the grid structures, according to a second exemplary embodiment; and

FIG. 8 is a perspective view illustrating grid structures, according to a third exemplary embodiment of the present invention,

### DESCRIPTION OF THE EMBODIMENTS

Hereinafter, the embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art.

When a certain layer, say layer A, is described to be formed on another layer, say layer B (or a wafer), it will means either that the layer A is formed directly on the layer B (or a wafer), or that a different layer, say layer C, is interposed between the layer A and layer B (or a wafer). In addition, thickness of layers or areas in drawings will be exaggerated for an effective description of the art related. In various exemplary embodiments of the present invention, the words such as first, second, third, etc. will be used for denoting various areas or layers. These words will be used just to point or differentiate a specific area or layer from the other areas or layers. Therefore, a layer can be denoted as a first layer in an exemplary embodiment, and the same layer can be denoted as a second layer in describing another exemplary embodiment.

FIG. 3 is a perspective view showing a grid structure according to an exemplary embodiment.

Referring to FIG. 3, the grid structure 100 includes a body 110, a bar-shaped holder 120 attached to a side of the body 110 and spanning across one end of the body 110 to the other, and an adhesive 130 interposed between the body 110 and the bar-shaped holder 120.

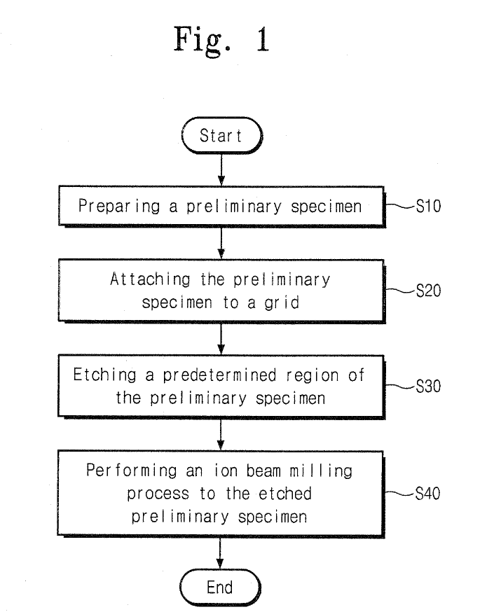

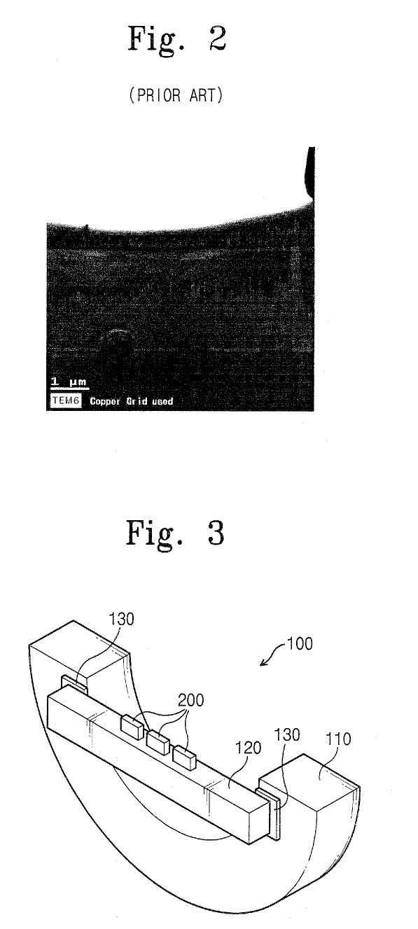

According to an embodiment, a specimen 200 may be attached to the bar-shaped holder 120. To describe in detail, a preliminary specimen of a proper size is prepared so that it is big enough to contain a target area for measurement (S10 in FIG. 1). Then the preliminary specimen may be attached to the bar-shaped holder 120 (S20 in FIG. 1). The preliminary specimen may be produced by etching the circumferential area of the preliminary specimen with the FIB. To attach the preliminary specimen to the bar-shaped holder 120, a deposition function of the FIB can be used: the attaching of the preliminary specimen to the bar-shaped holder 120 (S20) may include placing a bar adjacent to the preliminary specimen, attaching the preliminary specimen to the bar using the deposition function of the FIB, placing the preliminary specimen now attached to the bar adjacent to the bar-shaped holder 120, and attaching the preliminary specimen using again the deposition function of the FIB. Then, the bar may be detached from the preliminary specimen using the etching function of the FIB. A number of specimens 200 can be attached to the bar-shaped holder 120 in this way, as shown in FIG. 3.

A specific area of the preliminary specimen, i.e., a target area for the measurement, is etched with the etching function of the FIB (S30 in FIG. 1). The preliminary specimen may be etched so that the target area for the measurement is located in a center of the preliminary specimen. The etching process of the FIB may use argon ions accelerated in electric voltages of about 30 kV. As mentioned in the Discussion of the Related Art, the accelerated ions inflict damage to the surface of the specimen. Therefore, after the etching process of the FIB, the ion beam milling process is carried out in order to remove any damaged area (S40 in FIG. 1). The ion beam milling process may use gallium ions accelerated in electric voltages of about 3 kV. After the ion beam milling process, the preliminary specimen acquires an appropriate depth that can be properly measured with TEM (Transmission Electron Microscopy).

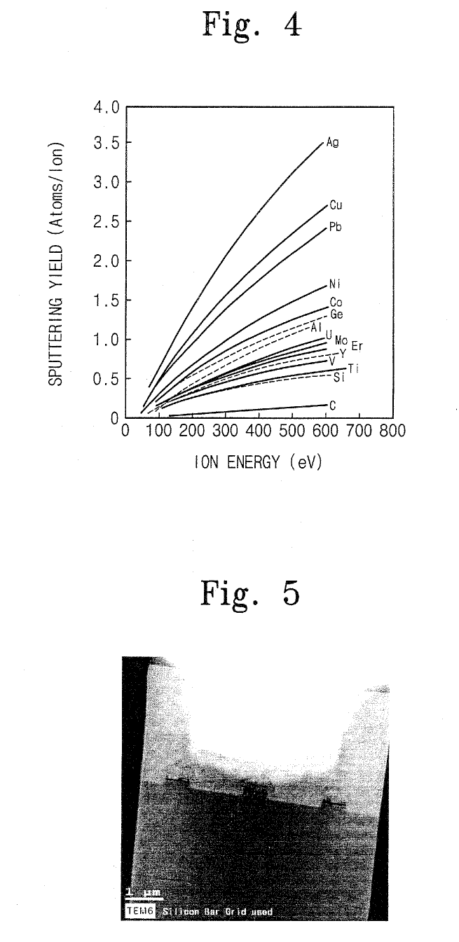

However, as described in the Discussion of the Related Art, the FIB etching process or the ion beam milling process etches not only the specimen but also the bar-shaped holder 120, and consequently the re-deposition problem may arise. In order to minimize the re-deposition, the bar-shaped holder 120 of some embodiments is made up of material resistant to etch by ion collision. For example, the bar-shaped holder 120 can be made up of at least one type of material selected from silicon, titanium, vanadium, yttrium, or molybdenum. Preferably, the bar-shaped holder 120 is made up of silicon of a single crystal structure similar to that produced from a typical semiconductor wafer. The required etch-resistant property of the materials listed above (i.e., silicon, titanium, vanadium, yttrium, and molybdenum) can be demonstrated by measurements of sputtering rates of various materials, as shown in FIG. 4.

FIG. 4 is a graph illustrating sputtering yields measured from various materials. In this experiment, an ion beam of argon is discharged at various materials and the number of ejected atoms from various materials is counted. The sputtering yield denotes the ratio of number of the atoms ejected to the number of argon ions hit. The horizontal axis of the graph in FIG. 4 denotes the energy of argon ions, and the vertical axis denotes the sputtering yield. (At this time, the sputtering yield is a dimensionless number, because it is the number of ejected atoms divided by the number of argon ions.) The sputtering yield of silicon, titanium, vanadium, yttrium, and molybdenum (which are used for the bar-shape holder 120 in an exemplary embodiment) are respectively 0.45, 0.5, 0.65, 0.7, and 0.8 for 500 eV and using argon ions, while the sputtering yield of copper and nickel (which are used for the grid in the prior art) are respectively 2.4 and 1.5 for the same condition. In conclusion, silicon, titanium, vanadium, yttrium, and molybdenum are more resistant against ion etch than copper or nickel, thereby improving the quality of image produced by the TEM (Transmission Electron Microscopy). As shown in FIG. 5, deteriorated images of TEM imagery, mentioned in the Discussion of The Related Art, did not occur in the TEM image of the present embodiment.

In addition, for the exemplary embodiment wherein the bar-shaped holder 120 is made up of silicon, the bar-shaped holder 120 can be fabricated without any other extra process such as, for instance, an additional coating process, since silicon is the material almost always used for fabricating semiconductor devices.

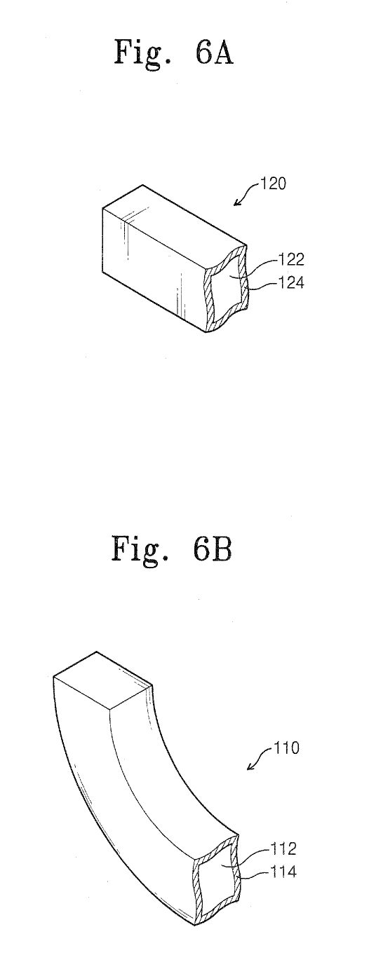

In an embodiment, referring to FIG. 6a, the bar-shaped holder 120 may include an internal bar 122 and a coating film 124 wrapping a surface of the internal bar 122. The coating film 124 is made up of at least one type of material selected from silicon, titanium, carbon, vanadium, yttrium, or molybdenum, and the internal bar 122 is, like the other embodiments, made up of at least one type of material selected from silicon, titanium, vanadium, yttrium, or molybdenum. In a preferred embodiment, the coating film 124 is made up of carbon and the internal bar 122 of silicon of a single crystal structure fabricated from the wafer.

Referring to FIG. 4, the sputtering yield of carbon is about 0.1 for argon ions at 500 eV of energy. Therefore, the embodiment that uses carbon for the coating film 124 can effectively reduce the re-deposition problem. Because of such a low yield of carbon, an entire part of the bar-shaped holder 120 can be made up of carbon.

Furthermore, according to the present embodiment, the body 110 also can be made up of material that is resistant against etch by ion collision. For example, the body 110, like the bar-shaped holder 120, may be made up of at least one type of material selected from silicon, titanium, vanadium, yttrium, or molybdenum. Preferably, the body 110 is made up of silicon of a single crystal structure that is produced from a typical semiconductor wafer. Here, the obtainable advantage and effectiveness are the same with the case wherein the bar-shaped holder 120 is made up of materials which are resistant against the ion etch. Since the yield of carbon is so low as well, an entire part of the body 110 can be made up of carbon.

In another embodiment shown in FIG. 6b, the body 110 may include an internal body 112 and an external body 114. Here, the internal body 112 is made up of at least one type of material selected from silicon, titanium, vanadium, yttrium, or molybdenum, and the outer body 114 is made up of at least one type of material selected from silicon, titanium, carbon, vanadium, yttrium, or molybdenum. In a preferred embodiment, the internal body 112 may be made up of silicon of a single crystal structure, the silicon fabricated from the wafer, and the outer body 114 a carbon layer wrapping the internal body 112.

The adhesive 130 is to attach the bar-shaped holder 120 to the body 110. Various kinds of material sticking can be used as the adhesive 130 for the attaching. Especially, according to the embodiments of the present invention described as above, the bar-shaped holder 120 and the body 110 can be separated, so the FIB etch and the ion beam milling can be carried out against the preliminary specimen attached just to the bar-shaped holder 120 without the body 110. In this case, there is no need for restricting the kinds of material used as the adhesive 130. However, in another embodiment of the present invention, the FIB etch and the ion beam milling can be carried out against the preliminary specimen with both the bar-shaped holder 120 and the body 110. In this case, the kinds of material used as the adhesive 130 can be restricted to avoid the re-deposition by metals. The adhesive 130 made up of carbon may be adopted for this case.

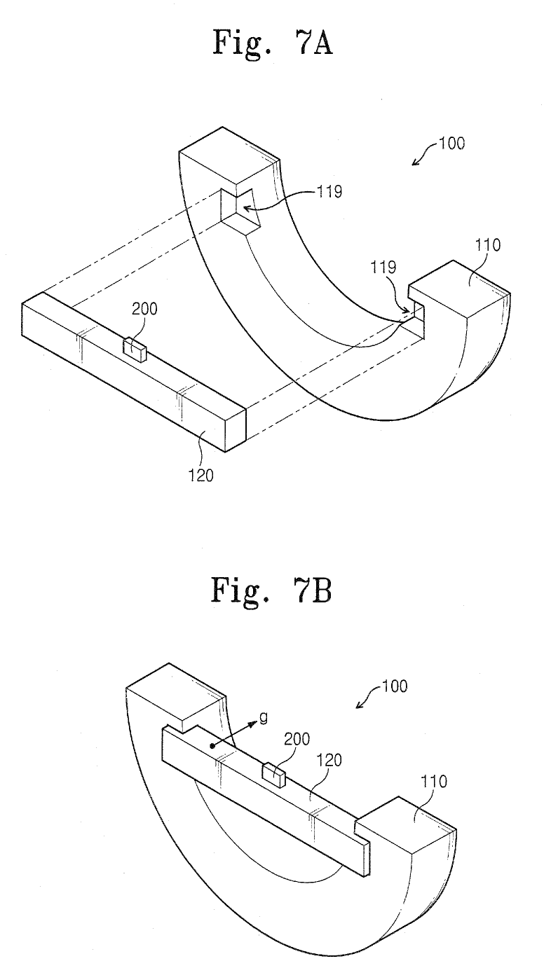

In another embodiment, the body 110 includes connecting grooves 119 for accepting and securing both end-portions of the bar-shaped holder 120 (refer to FIG. 7A). The bar-shaped holder 120 may be inserted to the connecting grooves 119, and thereby is fixed against the body 110 (refer to FIG. 7A and FIG. 7B). When the grid structure 100 is installed in the TEM (Transmission Electron Microscopy), gravity is perpendicular to a contact plane between the bar-shaped holder 120 and the body 110 (refer to FIG. 7). Therefore, in this embodiment, it is possible that no adhesives are required for fixing the bar-shaped holder 120 against the body 110. The connecting grooves 119 can be formed at any proper locations of the body 110, depending on the direction of gravity relative to the orientation of the grid structure 100. This embodiment has an advantage that any re-deposition caused by the adhesive 130 can be completely prevented.

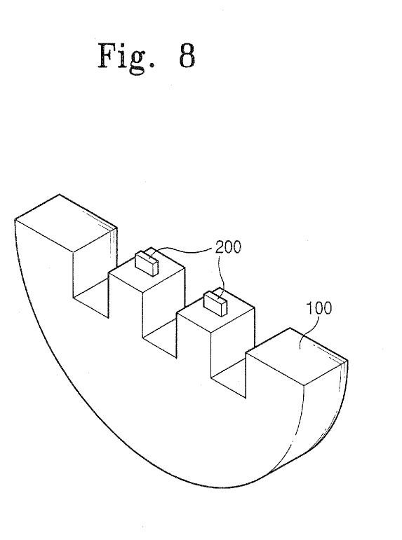

The re-deposition and the contamination described above are not necessarily related to a shape of the grid, but with material properties of the grid. Therefore, the grid structure 100 of the present embodiment should not be restricted to the particular shape of the grid presented as above. The grid structure 100 of the present embodiment, referring to FIG. 8, can include just a single holder without the bar-shaped holder 120. It is preferred in this embodiment also that the grid structure 100 be made up of materials that are resistant to the ion etch, the materials that are selected from, for example, silicon, titanium, carbon, vanadium, yttrium, or molybdenum.

Although the present invention has been described in connection with embodiments of the present invention illustrated in the accompanying drawings, it is not limited thereto. It will be apparent to those skilled in the art that various substitutions, modifications, and changes may be thereto without departing from the scope and spirit of the invention.

What is claimed is:

1. A grid structure for electronic microscopy comprising:
a first specimen holder for holding a specimen, the first specimen holder including on a surface adapted to be adjacent to the specimen a material resistant to etch by ion collision.

2. The grid structure of claim 1, wherein the material of the first specimen holder comprising at least one selected from the group consisting of silicon, titanium, carbon, vanadium, yttrium, or molybdenum.

3. The grid structure of claim 1, wherein a surface of the first specimen holder includes a coating film of a material selected from the group consisting of silicon, titanium, carbon, vanadium, yttrium, or molybdenum, said first specimen holder including an inner bar surrounded by the coating film.

4. The grid structure of claim 3, wherein the coating film material of the first specimen holder is carbon and the internal bar is formed of silicon of a single crystal structure.

5. The grid structure of claim 1, further including a second specimen holder, coupled to the first specimen holder, for holding the first specimen holder.

6. The grid structure of claim 5, wherein the second specimen holder is formed of a material consisting at least of one selected from the group consisting of silicon, titanium, carbon, vanadium, yttrium, or molybdenum.

7. The grid structure of claim 5, wherein a surface of the second specimen holder includes a coating film of a material selected from the group consisting of silicon, titanium, carbon, vanadium, yttrium, or molybdenum.

8. The grid structure of claim 7, wherein the coating film material of the second specimen holder is carbon and the internal bar is formed of silicon of a single crystal structure.

9. The grid structure of claim 1, wherein the material of the first specimen holder is entirely carbon.

10. The grid structure of claim 5, further including a combining structure affixing the first specimen holder to the second specimen holder.

11. The grid structure of claim 10, wherein the combining structure includes an adhesive.

12. The grid structure of claim 10, further including complementary grooves formed in both the first specimen holder and the second specimen holder.

13. A grid structure for electronic microscopy comprising:
a specimen holder for holding a specimen, the specimen holder made up of at least one selected from the group consisting of silicon, titanium, carbon, vanadium, yttrium, or molybdenum; and
a combining device interposed between the specimen holder and the specimen to fix the specimen to the specimen holder.

14. The grid structure of claim 13, wherein a surface of the specimen holder is coated with at least one selected from the group consisting of silicon, titanium, carbon, vanadium, yttrium, or molybdenum.

15. The grid structure of claim 13, further including a body adapted to support the specimen holder, wherein the body includes connecting grooves adapted to receive and support the specimen holder.

16. The grid structure of claim 15, wherein the combining device includes an adhesive to fix the specimen holder to the body.

17. The grid structure of claim 13, further including a body adapted to support the specimen holder, the body including an internal body and an external body that encases the internal body, wherein the internal body comprises single crystal silicon and the external body comprises carbon.

18. A grid structure for electronic microscopy of a specimen, the grid structure comprising:
a bar-shaped holder to support the specimen, the bar-shaped holder including an internal bar and a coating film, wherein the coating film encases the internal bar; and
an arcuate-shaped body adapted to support the bar-shaped holder, wherein the bar-shaped holder spans across the body.

19. The grid structure of claim 18, wherein the internal bar and the coating film both comprise materials that have a sputtering yield less than 1.

20. The grid structure of claim 18, wherein the internal bar and the coating film both comprise carbon.

21. The grid structure of claim 18, wherein the body includes an internal body and an external body that encases the internal body, and wherein the internal body comprises silicon of a single crystal structure.

22. The grid structure of claim 21, wherein the external body comprises carbon.
